(19) United States
(12) Patent Application Publication
(10) Pub. No.: US 2024/0421193 A1
(43) Pub. Date: Dec. 19, 2024

(54) Low Contact Resistance in Semiconductor Devices with Implanted Regions

(71) Applicant: Wolfspeed, Inc., Durham, NC (US)

(72) Inventors: Kyle Bothe, Cary, NC (US); Jia Guo, New Hill, NC (US); Christer Hallin, Hillsborough, NC (US); Alexander V. Suvorov, Durham, NC (US); Chris Hardiman, Cary, NC (US); Scott Sheppard, Chapel Hill, NC (US)

(21) Appl. No.: 18/333,632

(22) Filed: Jun. 13, 2023

(51) Int. Cl. H01L 29/20; H01L 29/205; H01L 29/45; H01L 29/66; H01L 29/778

(52) U.S. Cl. CPC H01L 29/2003; H01L 29/205; H01L 29/452; H01L 29/66462; H01L 29/7787

(57) ABSTRACT

Semiconductor devices with reduced contact resistance of ohmic contacts are provided. In one example, the semiconductor device includes a Group III-nitride semiconductor structure. The Group III-nitride semiconductor structure includes a channel layer and a barrier layer on the channel layer. The semiconductor device includes an implanted region extending into the channel layer. The implanted region includes a distribution of implanted dopants. The semiconductor device includes a recess in the implanted region. The recess extends through the barrier layer into the channel layer. The semiconductor device includes an ohmic contact within the recess.

### FIELD

The present disclosure relates generally to semiconductor devices, and more particularly to transistor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide bandgap semiconductor materials (e.g., having a bandgap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide bandgap semiconductor materials such as silicon carbide (e.g., 2.996 eV bandgap for alpha silicon carbide at room temperature) and the Group III-nitrides (e.g., 3.36 eV bandgap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor device. The semiconductor device includes a Group III-nitride semiconductor structure. The Group III-nitride semiconductor structure includes a channel layer and a barrier layer on the channel layer. The semiconductor device includes an implanted region extending into the channel layer. The implanted region includes a distribution of implanted dopants. The semiconductor device includes a recess in the implanted region. The recess extends through the barrier layer into the channel layer. The semiconductor device includes an ohmic contact within the recess.

Another example embodiment of the present disclosure is directed to a transistor device. The transistor device includes a Group III-nitride semiconductor structure. The Group III-nitride semiconductor structure includes a channel layer and a barrier layer on the channel layer. The transistor device includes a gate contact on the barrier layer. The gate contact has a gate length of less than about 100 nm. The transistor device includes an implanted region in the Group III-nitride semiconductor structure. The implanted region has a distribution of implanted dopants. The transistor device has an ohmic contact on the implanted region. A contact resistance of the ohmic contact with the Group III-nitride semiconductor structure is about 0.15 ohm-mm or less.

Another example embodiment of the present disclosure is directed to a method of forming a semiconductor device. The method includes forming a Group III-nitride semiconductor structure on a substrate, the Group III-nitride semiconductor structure having a channel layer and a barrier layer on the channel layer. The method includes implanting dopants in the Group III-nitride semiconductor structure to form an implanted region in the Group III-nitride semiconductor structure, the implanted region having a distribution of implanted dopants extending into the channel layer. The method includes forming a recess in the implanted region, the recess extending through the barrier layer into the channel layer. The method includes forming an ohmic contact in the recess.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of an example HEMT device according to example embodiments of the present disclosure.

FIG. 2 depicts a cross-sectional view of the semiconductor structure on the substrate according to example embodiments of the present disclosure.

FIG. 3 depicts a cross-sectional view of the semiconductor structure on the substrate including an implanted region according to example embodiments of the present disclosure.

FIG. 4 depicts a cross-sectional view of the semiconductor structure on the substrate including an implanted region according to example embodiments of the present disclosure.

FIG. 5 depicts a cross-sectional view of an example HEMT device according to example embodiments of the present disclosure.

FIG. 6 depicts a plot of contact resistance from example semiconductor devices according to example embodiments of the present disclosure.

FIG. 7 depicts a plot of implant dimension measurements from example semiconductor devices according to example embodiments of the present disclosure.

FIG. 8 depicts a plot of peak drain cut-off current for example semiconductor devices according to example embodiments of the present disclosure.

FIG. 9 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Transistor devices, such as high electron mobility transistors (HEMTs), may be used in power electronics applications. HEMTs fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors or as coupled with other circuit elements, such as in monolithic microwave integrated circuit (MMIC) devices.

Transistor devices such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different bandgap energies, where the smaller bandgap material has a higher electron affinity. The 2DEG is an accumulation layer in the smaller bandgap material and can include a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Group III nitride-based HEMT devices present strong opportunities for increasing higher frequency capabilities and/or higher power added efficiency. Higher-frequency applications can benefit from smaller devices, such as transistors having gate lengths of about 100 nm (or less). As the devices are made smaller, it can be necessary to reduce contact resistances of ohmic contacts (e.g., source contacts or drain contacts) at the device. For instance, some high-frequency applications can benefit from contact resistances below 0.15 ohm-mm. Some attempts to achieve these lower contact resistances employ GaN-doped regrown ohmic contacts. For instance, one existing approach to create ohmic contacts with lower than 0.15 ohm-mm contact resistances employs the use of GaN N+ doped regrowth by epitaxial growth. However, regrown-doped GaN contacts can suffer from several issues, including costly and complex fabrication methods, additional fabrication time associated with epitaxial growth, and uneven growth resulting in non-planar contacts.

Examples of the present disclosure provide semiconductor devices and methods of fabrication that can achieve the performance metric of less than 0.15 ohm-mm contact resistances without utilizing GaN-doped regrown ohmic contacts. For instance, a semiconductor device may have a barrier layer and a channel layer. The barrier layer can be a thin barrier layer, such as a barrier layer having a thickness of about 130 Angstroms or less. Additionally or alternatively, the barrier layer can include a Group-III-nitride (e.g., AlGaN) with a high aluminum mole fraction, such as an aluminum mole fraction in a range of about 25% to about 40%.

An implanted region can extend into the channel layer. The implanted region can have implanted dopants to provide, for instance, N-type doping of the semiconductor structure in the implanted region. For example, the implanted dopants can include silicon, germanium, and/or other suitable dopants. The implanted region can extend to a depth of about 200 Angstroms to about 300 Angstroms beneath a surface of the Group II-nitride semiconductor structure. A recess can be formed (e.g., etched) in the implanted region, which can extend through the barrier layer into the channel layer. An ohmic contact can be formed within the recess. For instance, the recess can include a metal suitable to form an ohmic contact with the channel layer.

Semiconductor devices according to examples of the present disclosure can achieve contact resistances below 0.15 ohm-mm. Furthermore, the examples of the present disclosure can be applicable to several semiconductor devices, such as GaN HEMTs and planar GaN transistors, over several ranges of operating frequencies, including operating frequencies from about 8 GHz to about 12 GHz (e.g., x-band), operating frequencies from about 12 GHz to about 18 GHz (e.g., ku-band), operating frequencies from about 18 GHz to about 27 GHz (e.g., k-band), operating frequencies from about 27 GHz to about 40 GHz (e.g., ka-band), operating frequencies from about 40 GHz to about 75 GHz (V-band), and/or operating frequencies from about 75 GHz to about 110 GHz (W-band), and/or any other suitable operating frequencies.

Aspects of the present disclosure provide a number of technical effects and benefits. For instance, the present inventors have discovered that semiconductor devices including a Group III-nitride semiconductor structure including a thin barrier layer with higher aluminum mole fraction, and further including implanted regions extending through the barrier layer and/or into the channel layer having a distribution of implanted dopants, and further including a recess in the implanted region having an ohmic contact within the recess provide for significantly lower contact resistances at the ohmic contact, such as contact resistances less than about 0.15 ohm-mm. The lower contact resistance can provide for improved efficiency (e.g., improved power added efficiency (PAE)) and/or improved operating characteristics at higher frequencies. Furthermore, the semiconductor structures can avoid several drawbacks associated with the use of regrown GaN ohmic contacts, such as increased manufacturing time and/or cost and/or formation of non-planar contacts.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the present disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other transistor devices without deviating from the scope of the present disclosure. For instance, aspects of the present disclosure may be implemented in any transistor having a field plate or other transistors devices with metal structures, such as silicon carbide-based MOSFETS.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

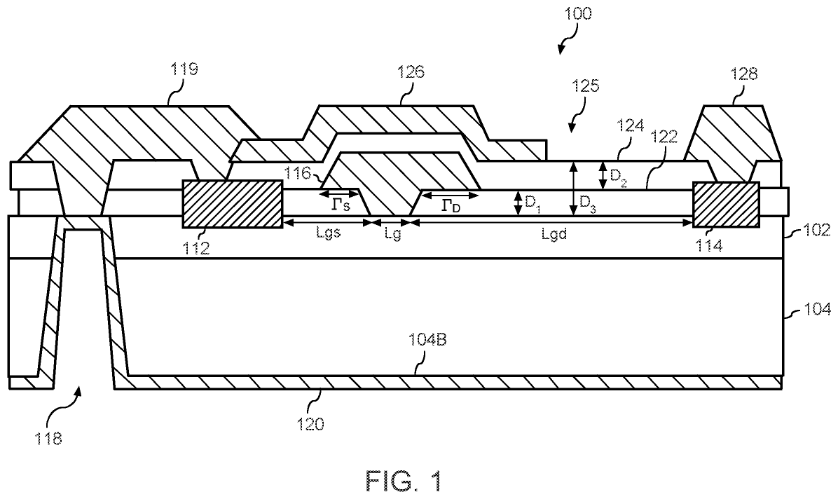

FIG. 1 depicts a cross-sectional view of an example HEMT device 100 according to example embodiments of the present disclosure. FIG. 1 is intended to represent structures for identification and description and is not intended to represent the structures to physical scale. The HEMT device 100 may include a semiconductor structure 102. The semiconductor structure 102 may be a Group III-nitride semiconductor structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861. U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100 that may include one or more transistor cells.

In some embodiments, the substrate 104 of the HEMT device 100 may be a thinned substrate 104. In some embodiments, the thickness of the substrate 104 may be about 100 μm or less, such as about 75 μm or less, such as about 50 μm or less.

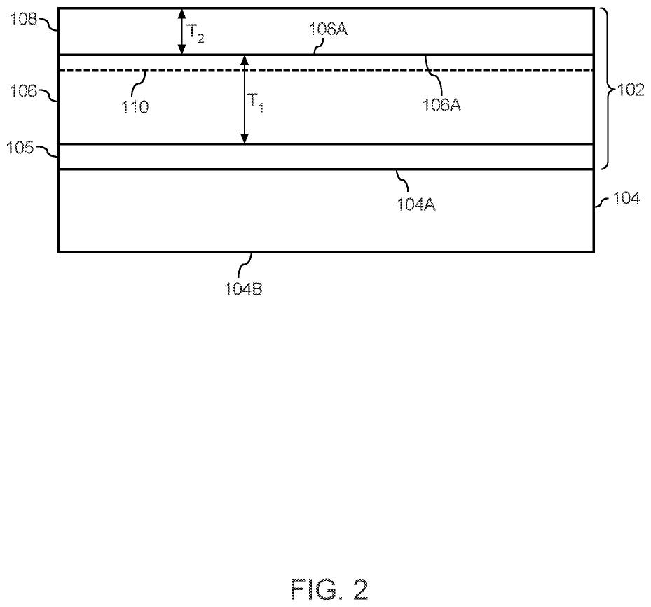

FIG. 2 depicts a cross-sectional view of the semiconductor structure 102 on the substrate 104. The semiconductor structure 102 may include a channel layer 106 on an upper surface 104A of the substrate 104 (or on the optional layers described further herein, such as an optional buffer or nucleation layer 105). The semiconductor structure 102 may include a barrier layer 108 on an upper surface of the channel layer 106. In some embodiments, the channel layer 106 and the barrier layer 108 may each be formed by epitaxial growth. Techniques for epitaxial growth of Group III-nitrides have been described in, for example, U.S. Pat. Nos. 5,210,051. 5,393,993, and 5,523,589, the disclosures of which are incorporated by reference herein. The channel layer 106 may have a bandgap that is less than the bandgap of the barrier layer 108. The channel layer 106 may have a larger electron affinity than the barrier layer 108. The channel layer 106 and the barrier layer 108 may include Group III nitride-based materials.

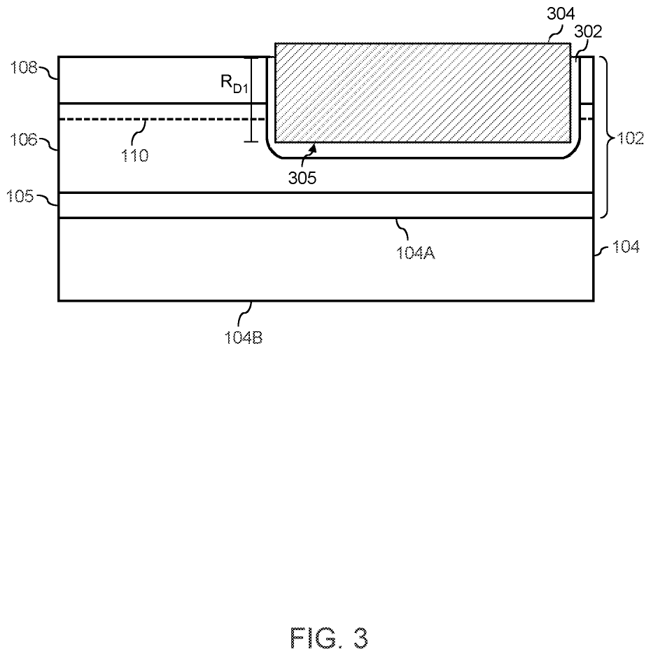

In some embodiments, the channel layer 106 may be a Group III-nitride, such as AlₓGa₁₋ₓN, where x is about 0.1 or less, provided that the energy of the conduction band edge of the channel layer 106 is less than the energy of the conduction band edge of the barrier layer 108 at the interface between the channel layer 106 and barrier layer 108. In some embodiments, the aluminum mole fraction x is approximately 0 (e.g., less than 5%, such as 0%), indicating that the channel layer 106 is GaN. The channel layer 106 may or may not include other Group III-nitrides such as InGaN, AlInGaN or the like. The channel layer 106 may be undoped (“unintentionally doped”). In some examples, the channel layer 106 may be doped, for instance with iron (Fe). The channel layer 106 may have a thickness T₁ of about 0.5 μm to about 5 μm, such as about 1.4 μm. The channel layer 106 may be a multi-layer structure, such as a superlattice or combinations of GaN, AlGaN or the like. The channel layer 106 may be under compressive strain in some embodiments. According to the present disclosure, the channel layer 106 can include an implanted region extending into the channel layer 106. The implanted region may have implanted dopants to provide, for instance, N-type doping of the semiconductor structure in the implanted region. The implanted region will be discussed in further detail below (e.g., with respect to FIG. 3).

The barrier layer 108 includes a Group III nitride-based layer having a surface 108A positioned on a surface 106A of the channel layer 106. The barrier layer 108 may be a Group III-nitride, such as Al_{y}Ga_{1-y}N, where y is the aluminum mole fraction in the barrier layer 108. In some embodiments, the aluminum mole fraction y is such that y is in a range of about 0.25 to about 0.40 (e.g., the aluminum mole fraction is in a range of about 25% to about 40%), indicating that the barrier layer is an AlGaN layer. For instance, in some embodiments, the aluminum mole fraction y is such that y is in a range from about 0.25 to about 0.35, such as about 0.25 to 0.30, such as about 0.30 (e.g., the aluminum mole fraction is in a range of about 25% to about 35%, such as about 25% to about 30%, such as about 30%). Additionally or alternatively, in some embodiments, the aluminum mole fraction y is such that y is in a range of about 0.30 to about 0.40, such as about 0.35 to about 0.40, such as about 0.35 (e.g., the aluminum mole fraction is in a range of 30% to 40%, such as in a range of about 35% to about 40%, such as about 35%). For instance, in some implementations, the barrier layer 108 can include a higher aluminum mole fraction to achieve low contact resistance for high frequency applications, as discussed herein.

The energy of the conduction band edge of the barrier layer 108 is greater than the energy of the conduction band edge of the channel layer 106 at the interface between the channel layer 106 and barrier layer 108. The barrier layer 108 may include other Group III elements (e.g., In) without deviating from the scope of the present disclosure. The barrier layer 108, in some examples, may be a multilayer structure. The multilayer structure may include multiple Group III nitride-based layers with differing aluminum mole fractions.

The barrier layer 108 may have a thickness T₂. The thickness T₂ may be less than about 130 Angstroms, such as in a range of about 10 Angstroms to about 130 Angstroms. For instance, in some embodiments, the barrier layer can have a thickness in a range of about 70 Angstroms to about 100 Angstroms, such as about 80 Angstroms to about 90 Angstroms. For instance, in some implementations, the barrier layer 108 can have a reduced thickness to achieve low contact resistance for high frequency applications, as discussed herein. The channel layer 106 and/or the barrier layer 108 may be deposited, for example, by metal-organic chemical vapor deposition (MOCVD), molecular beam epitaxy (MBE), or hydride vapor phase epitaxy (HVPE).

A 2DEG 110 may be induced in the channel layer 106 at an interface between the channel layer 106 and the barrier layer 108. The 2DEG 110 is highly conductive and allows conduction between the source and drain regions of the HEMT device 100.

While the HEMT device 100 of FIGS. 1-4 is shown with a substrate 104, channel layer 106 and barrier layer 108 for purposes of illustration, the HEMT device 100 may include additional layers/structures/elements. For instance, the HEMT device 100 may include a buffer layer(s)/nucleation layer(s)/transition layer(s) 105 between substrate 104 and the channel layer 106. For example, an AIN buffer layer may be on the upper surface 104A of the substrate 104 to provide an appropriate crystal structure transition between a SiC substrate 104 and the channel layer 106. The optional buffer/nucleation/transition layers 105 may be deposited by MOCVD, MBE, and/or HYPE.

The HEMT device 100 may include a cap layer (not illustrated) on the barrier layer 108. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

Referring to FIG. 1, the HEMT device 100 may include a source contact 112 on the semiconductor structure 102 or otherwise contacting the semiconductor structure 102. The HEMT device 100 may include a drain contact 114 on the semiconductor structure 102 or otherwise contacting the semiconductor structure 102. The source contact 112 and the drain contact 114 may be laterally spaced apart from each other. In some embodiments, the source contact 112 and the drain contact 114 may include a metal that may form an ohmic contact to a Group III nitride-based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 112 may be an ohmic source contact 112. The drain contact 114 may be an ohmic drain contact 114. Thus, the source contact 112 and/or the drain contact 114 may include an ohmic contact portion in direct contact with the barrier layer 108. In some embodiments, the source contact 112 and/or the drain contact 114 may include a plurality of layers to form an ohmic contact that may be provided as described, for example, in U.S. Pat. Nos. 8,563,372 and 9,214,352, the disclosures of which are incorporated by reference herein.

According to example aspects of the present disclosure, the ohmic contact(s) formed by the source contact 112 and/or the drain contact 114 can have a decreased contact resistance. For instance, example aspects of the present disclosure can provide for a decrease in contact resistance of the ohmic contact(s) compared to some existing semiconductor devices. For instance, in some embodiments, a contact resistance of the ohmic contact with the Group III-nitride semiconductor structure as described herein can be about 0.15 ohm-mm or less, such as about 0.10 ohm-mm or less, such as within a range of about 0.05 to about 0.15 ohm-mm.

The HEMT device 100 may include a gate contact 116 on the semiconductor structure 102 or otherwise contacting the semiconductor structure 102 (e.g., at least partially recessed into the semiconductor structure 102). The gate contact 116 may have a gate length LG. The gate length LG may be the length of the gate contact 116 along the portion of the gate contact 116 that is on the semiconductor structure 102 (e.g., the length of the lowermost portion of the gate contact 116 in contact with the semiconductor structure 102). In some embodiments, the gate length LG may be about 200 nm or less, such as about 100 nm or less, such as in a range of about 60 nm to about 100 nm, such as in a range of about 70 nm to about 90 nm. A distance Lgd between the gate contact 116 and the drain contact 114 may be, for instance, in a range of 1.8 μm to about 2.2 μm, such as about 1.98 μm. A distance Lgs between the gate contact 116 and the source contact 112 may be, for instance, in a range of about 0.4 μm to about 0.8 μm, such as about 0.6 μm.

The material of the gate contact 116 may be chosen based on the composition of the barrier layer 108, and may, in some embodiments, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSIN).

In some embodiments, the gate contact 116 may be a T-shaped gate and/or a gamma gate, the formation of which is discussed by way of example in U.S. Pat. Nos. 8,049,252, 7,045,404, and 8,120,064, the disclosures of which are incorporated by reference herein. The gate contact 116 may have an overhang toward the drain contact 114. The length Γ_{D} of the overhang toward the drain contact 114 may be in a range of about 0.15 μm to about 0.25 μm, such as about 0.2 μm. The gate contact 116 may have an overhang toward the source contact 112. The length Γ_{S} of the overhang toward the source contact 112 may be in a range of about 0.15 μm to about 0.25 μm, such as about 0.2 μm.

The source contact 112 may be coupled to a reference signal such as, for example, a ground voltage or other reference signal. The coupling to the reference signal may be provided by a via 118 that extends from a lower surface 104B of the substrate 104, through the substrate 104 and semiconductor structure 102 to the upper surface of the semiconductor structure 102. The via 118 may be coupled to a metal contact 119. The metal contact 119 may include metal or other highly conductive material, including, for example, copper, cobalt, gold, and/or a composite metal. The metal contact 119 may conductively couple the via 118 to the source contact 112. A back metal layer 120 may be on the lower surface 104B of the substrate 104 and on side walls of the via 118. The back metal layer 120 may be conductively coupled to the metal contact 119. Thus, the back metal layer 120, and a signal coupled thereto, may be electrically connected to the source contact 112 through the metal contact 119.

In some embodiments, the via 118 may have an oval or circular cross-section when viewed in a plan view. However, the present disclosure is not limited thereto. In some embodiments, a cross-section of the via 118 may be a polygon or other shape, as will be understood by one of ordinary skill in the art using the disclosures provided herein. In some embodiments, dimensions of the via (e.g., a length and/or a width) may be such that a largest cross-sectional area of the via 118 is about 1000 μm² or less. The cross-sectional area may be taken in a direction that is parallel to the lower surface 104B of the substrate 104 (e.g., the X-Y plane of FIG. 1). In some embodiments, the largest cross-sectional area of the via 118 may be that portion of the via 118 that is adjacent the lower surface 104B of the substrate 104 (e.g., the opening of the via 118). For example, in some embodiments, a greatest width (e.g., in the X direction in FIG. 1) may be about 16 μm and a greatest length (e.g., in the Y direction in FIG. 1) may be about 40 μm, though the present disclosure is not limited thereto. In some embodiments, sidewalls of the via 118 may be inclined and/or slanted with respect to the lower surface 104B of the substrate 104. In some embodiments, the sidewalls of the via 118 may be approximately perpendicular to the lower surface 104B of the substrate 104.

Depending on the embodiment, the drain contact 114 may be formed on, in and/or through the semiconductor structure 102, and there may be dopant implantation into the materials around the drain contact 114 to reduce resistivity and provide improved ohmic contact to the semiconductor material. In yet other embodiments, there is no source via 118, and the source contact 112 is formed on, in and/or through the semiconductor structure 102, and there may be implantation in the materials around the source contact 112 to reduce resistivity and provide improved ohmic contact to the semiconductor material. Where there is no source via 118, the electrical connections to the source contact 112 may be made on the same side as the gate contact 116 and the drain contact 114. In some examples, the connections to the source contact 112, drain contact 114, and/or gate contact 116 may be made from the top and/or the bottom to provide for flip chip configuration of the HEMT device 100. In some examples, thermal paths may be provided from the top and/or bottom to provide for flip chip configuration of the HEMT device 100.

The HEMT device 100 may include a dielectric structure 125 on the semiconductor structure 102. The dielectric structure 125 may include a first dielectric layer 122 and a second dielectric layer. The first dielectric layer 122 may directly contact the upper surface of the semiconductor structure 102. At least a portion of the first dielectric layer 122 may be between the semiconductor structure 102 and at least a portion of the gate contact 116. For instance, at least a portion of the first dielectric layer 122 may be between the semiconductor structure 102 and the overhang of the gate contact 116. The first dielectric layer 122 may have a thickness D₁. In some embodiments, the thickness D₁ of the first dielectric layer 122 may be about 1450 Angstroms or less, such as in a range of about 800 Angstroms to about 1450 Angstroms, such as about 1200 Angstroms. In this way, the overhang of the T-shaped or Gamma-shaped gate contact 116 may be separated from the semiconductor structure 102 by a distance approximately equal to D₁. The first dielectric layer 122 may be a SiN layer. Other suitable dielectric materials may be used without deviating from the scope of the present disclosure. For instance, the first dielectric layer 122 may be SiO₂, Si, Ge, MgOx, MgNx, ZnO, SiNx, SiOx, alloys or layer sequences thereof, or epitaxial materials.

The dielectric structure 125 may include a second dielectric layer 124 on the first dielectric layer 122. The second dielectric layer 124 may be the same dielectric material or a different dielectric material relative to the first dielectric layer 122. For instance, the second dielectric layer may be a SiN layer. Other suitable dielectric materials may be used without deviating from the scope of the present disclosure. For instance, the second dielectric layer 124 may be SiO₂, Si, Ge, MgOx, MgNx, ZnO, SiNx, SiOx, alloys or layer sequences thereof, or epitaxial materials. The second dielectric layer 124 may have a thickness D₂. In some embodiments, the thickness D₂ of the second dielectric layer 124 may be about 2800 Angstroms or less, such as in a range of about 1500 Angstroms to about 2800 Angstroms, such as about 2100 Angstroms.

The dielectric structure 125 may have a thickness D₃. In some embodiments, the thickness D₃ of the dielectric structure may be about 3600 Angstroms or less, such as in a range of about 3000 Angstroms to about 3600 Angstroms, such as about 3300 Angstroms.

One or more field plates 126 may be on the dielectric structure 125 as illustrated in FIG. 1. At least a portion of a field plate 126 may be overlapping the gate contact 116. At least a portion of the field plate 126 may be on a portion of the second dielectric layer 124. In some embodiments, the field plate 126 may be conductively coupled to the gate contact 116. The field plate 126 may reduce the peak electric field in the HEMT device 100, which may result in increased breakdown voltage and reduced charge trapping. The reduction of the electric field may also yield other benefits such as reduced leakage currents and enhanced reliability. Field plates and techniques for forming field plates are discussed, by way of example, in U.S. Pat. No. 8,120,064, the disclosure of which is incorporated by reference herein.

Metal contacts 119 and 128 may be in the dielectric structure 125 as illustrated in FIG. 1. The metal contacts 119 and 128 may provide interconnection between the source contact 112, drain contact 114, gate contact 116, and other parts of the HEMT device 100. Metal contact 119 may be conductively coupled to the source contact 112. Metal contact 128 may be conductively coupled to the drain contact 114. The metal contacts 119 and 128 may include metal or other highly conductive material, including, for example, copper, cobalt, gold, and/or a composite metal.

A HEMT transistor cell may be formed by the active region between the source contact 112 and the drain contact 114 under the control of the gate contact 116 between the source contact 112 and the drain contact 114. FIG. 1 depicts a cross-sectional view of one unit or cell of an HEMT device 100 for purposes of illustration. The HEMT device unit or cell may be formed adjacent to additional HEMT device cells and may share, for instance, a source contact 112 with adjacent HEMT device cells. The HEMT device 100 may be formed, at least in part, via wafer-level processing, and the wafer may then be diced to provide a plurality of individual HEMT devices 100.

FIG. 3 depicts a cross-sectional view of the semiconductor structure 102 on the substrate 104 including an implanted region 302 according to example embodiments of the present disclosure. The implanted region 302 includes a distribution of implanted dopants extending into the channel layer 108. The implanted dopants may provide, for instance, for N-type doping of the semiconductor structure 102. The implanted dopants may be, for instance, silicon or germanium dopants. The implanted region 302 may have a distribution of implanted dopants that extends to a depth from a surface (e.g., a top surface) of the semiconductor structure. The depth may be about 200 Angstroms or greater, such as about 250 Angstroms or greater, such as in a range of about 200 Angstroms to about 300 Angstroms. For instance, in some embodiments, the implanted region 302 can extend to a depth of about 200 Angstroms to about 300 Angstroms beneath a surface of the Group III-nitride semiconductor structure. In particular, the implanted region can extend completely through the barrier layer 108 and into the channel layer 106. The distribution of implanted dopants may extend through other layers, if present, such as a cap layer.

The implanted region 302 may have a peak dopant concentration. In some embodiments, a peak dopant concentration of the distribution of implanted dopants in the implanted region 302 is in the channel layer 106. For instance, the implanted region 302 may be doped such that the distribution of implanted dopants is greater at a portion of the implanted region 302 at a depth as the channel layer 106 than at a portion of the implanted region 302 at a depth as the barrier layer 108 (and/or another layer). In some examples, the distribution of implanted dopants may provide a substantially uniform concentration of implanted dopants throughout the implanted region 302 of the semiconductor structure 102. In some embodiments, a peak dopant concentration of the distribution of implanted dopants can be about 1×10¹⁸ dopants/cm³.

A recess 305 may be formed in the implanted region 302. The recess 305 may extend a depth R_{d1} into the semiconductor structure 102. The depth R_{d1} may extend into the channel layer 106. For instance, the depth Rd1 may be in a range of about 150 Angstroms or greater, such as about 200 Angstroms or greater, such as in a range of about 200 Angstroms to about 400 Angstroms.

An ohmic contact 304 (e.g., the source contact 112 or the drain contact 114 of FIG. 1) may be formed at least partially within the recess 305. The ohmic contact 304 may be directly on the implanted region 302 extending into the channel layer 106.

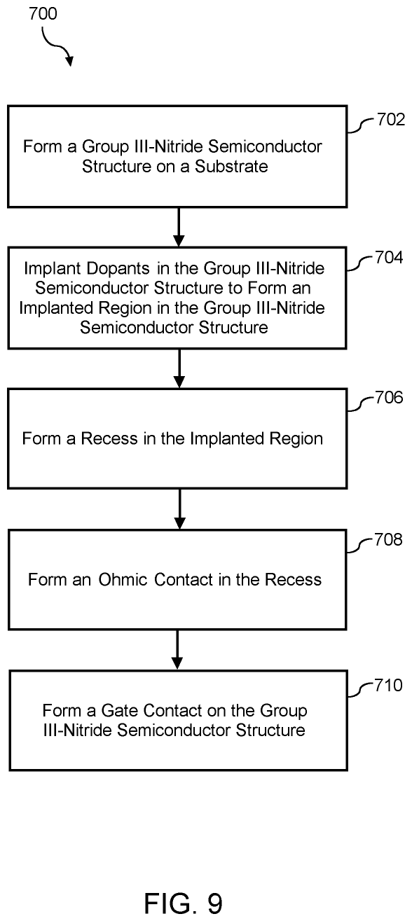

In some embodiments, the implanted region 302 can first be formed within the semiconductor structure 102 without a recess, such as by doping. The recess 305 can then be formed into the implanted region 302, such as by etching away portions of the implanted region 302. The ohmic contact 304 can then be formed within the recess, such as by metal deposition. Alternatively, however, the recess 305 may be formed prior to forming the implanted region 302. An example method of manufacturing the semiconductor structure 102 including the implanted region 302 and ohmic contact 304 is discussed further with respect to FIG. 9.

The implanted dopants within the implanted region 302 may provide a low resistive path between the ohmic contact 304 and the channel layer 106. For instance, the implanted region 302 may have a dopant concentration such that the implanted region 302 has a resistivity in a range of about 0.15 ohm-mm or less.

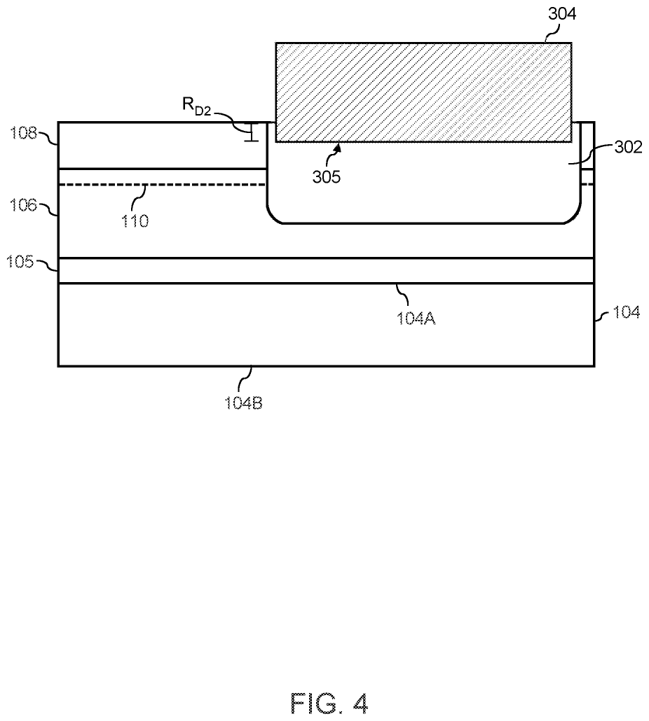

FIG. 4 depicts a cross-sectional view of the semiconductor structure 102 on the substrate 104 including an implanted region 302 according to example embodiments of the present disclosure. The example of FIG. 4 is similar to that of FIG. 3, except that the recess 305 does not extend into the channel layer. Rather, the recess 305 extends only into the barrier layer 108. For instance, the recess 305 extends to a depth R_{d2} of about 120 Angstroms or less, such as about 100 Angstroms or less, such as in a range of about 70 Angstroms to about 100 Angstroms. In this way, the ohmic contact 304 may be directly on the implanted region 302 in the barrier layer 108.

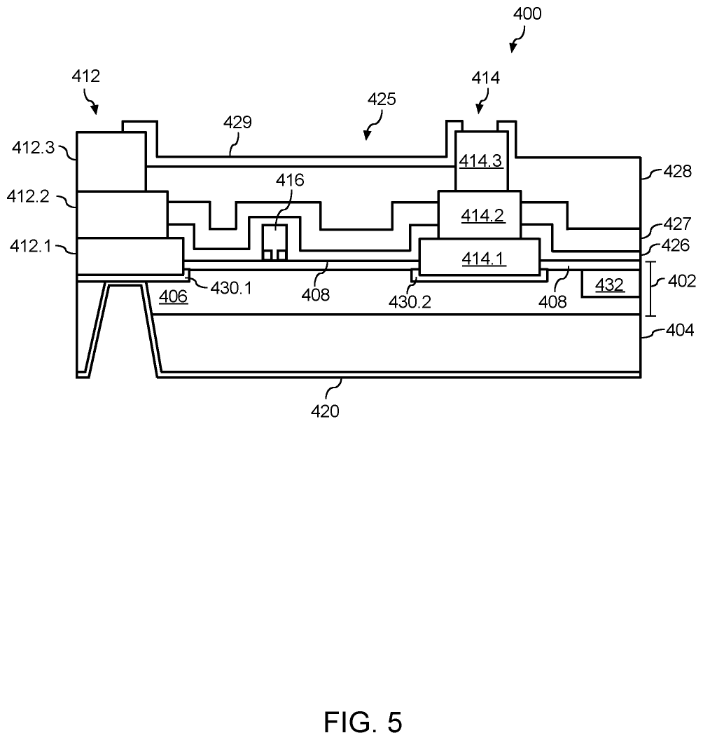

FIG. 5 depicts a cross-sectional view of an example HEMT device 400 according to example embodiments of the present disclosure. FIG. 5 is intended to represent structures for identification and description and is not intended to represent the structures to physical scale. The HEMT device 400 may include a semiconductor structure 402. The semiconductor structure 402 may be a Group III-nitride semiconductor structure.

The semiconductor structure 402 may be on a substrate 404. The substrate 404 may be a semiconductor material. For instance, the substrate 404 may be a silicon substrate, a silicon carbide (SiC) substrate, a sapphire substrate, or other suitable substrate. In some embodiments, the substrate 404 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 404 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 404 may be a SiC wafer, and the HEMT device 400 may be formed, at least in part, via wafer-level processing, and the wafer may then be diced to provide a plurality of individual HEMT devices 400 that may include one or more transistor cells.

In some embodiments, the substrate 404 of the HEMT device 400 may be a thinned substrate 404. In some embodiments, the thickness of the substrate 404 may be about 100 μm or less, such as about 75 μm or less, such as about 50 μm or less.

The semiconductor structure 402 may include a channel layer 406 on the substrate 404 (or on the optional layers described further herein, such as an optional buffer or nucleation layer). The semiconductor structure 402 may include a barrier layer 408 on the channel layer 406. In some embodiments, the channel layer 406 and the barrier layer 408 may each be formed by epitaxial growth. Techniques for epitaxial growth of Group III-nitrides have been described in, for example, U.S. Pat. Nos. 5,210,051, 5,393,993, and 5,523,589, the disclosures of which are incorporated by reference herein. The channel layer 406 may have a bandgap that is less than the bandgap of the barrier layer 408. The channel layer 406 may have a larger electron affinity than the barrier layer 408. The channel layer 406 and the barrier layer 408 may include Group III nitride-based materials.

In some embodiments, the channel layer 406 may be a Group III-nitride, such as AlₓGa₁₋ₓN, where x is about 0.1 or less, provided that the energy of the conduction band edge of the channel layer 406 is less than the energy of the conduction band edge of the barrier layer 408 at the interface between the channel layer 406 and barrier layer 408. In some embodiments, the aluminum mole fraction x is approximately 0 (e.g., less than 5%, such as 0%), indicating that the channel layer 406 is GaN. The channel layer 406 may or may not include other Group III-nitrides such as InGaN, AlInGaN or the like. The channel layer 406 may be undoped (“unintentionally doped”). In some examples, the channel layer 406 may be doped, for instance with iron (Fe). The channel layer 406 may have a thickness T₁ of about 0.5 um to about 5 μm, such as about 1.4 μm. The channel layer 406 may be a multi-layer structure, such as a superlattice or combinations of GaN, AlGaN or the like. The channel layer 406 may be under compressive strain in some embodiments.

The barrier layer 408 may be a Group III-nitride, such as Al_{y}Ga_{1-y}N, where y is the aluminum mole fraction in the barrier layer 408. In some embodiments, the aluminum mole fraction y is such that y is in a range of about 0.25 to about 0.40 (e.g., the aluminum mole fraction is in a range of about 25% to about 40%), indicating that the barrier layer is an AlGaN layer. For instance, in some embodiments, the aluminum mole fraction y is such that y is in a range from about 0.25 to about 0.35, such as about 0.25 to 0.30, such as about 0.30 (e.g., the aluminum mole fraction is in a range of about 25% to about 35%, such as about 25% to about 30%, such as about 30%). Additionally or alternatively, in some embodiments, the aluminum mole fraction y is such that y is in a range of about 0.30 to about 0.40, such as about 0.35 to about 0.40, such as about 0.35 (e.g., the aluminum mole fraction is in a range of 30% to 40%, such as in a range of about 35% to about 40%, such as about 35%). For instance, in some implementations, the barrier layer 408 can include a higher aluminum mole fraction to achieve low contact resistance for high frequency applications, as discussed herein.

The energy of the conduction band edge of the barrier layer 408 is greater than the energy of the conduction band edge of the channel layer 406 at the interface between the channel layer 406 and barrier layer 408. The barrier layer 408 may include other Group III elements (e.g., In) without deviating from the scope of the present disclosure. The barrier layer 408, in some examples, may be a multilayer structure. The multilayer structure may include multiple Group III nitride-based layers with differing aluminum mole fractions.

The barrier layer 408 may have a thickness of less than about 130 Angstroms, such as in a range of about 10 Angstroms to about 130 Angstroms. For instance, in some embodiments, the barrier layer 408 can have a thickness in a range of about 70 Angstroms to about 100 Angstroms, such as about 80 Angstroms to about 90 Angstroms. For instance, in some implementations, the barrier layer 408 can have a reduced thickness to achieve low contact resistance for high frequency applications, as discussed herein. The channel layer 406 and/or the barrier layer 408 may be deposited, for example, by metal-organic chemical vapor deposition (MOCVD), molecular beam epitaxy (MBE), or hydride vapor phase epitaxy (HVPE).

A 2DEG may be induced in the channel layer 406 at an interface between the channel layer 406 and the barrier layer 408. The 2DEG is highly conductive and allows conduction between the source and drain regions of the HEMT device 400.

While the HEMT device 400 of FIG. 5 is illustrated with substrate 404, channel layer 406 and barrier layer 408 for purposes of illustration, the HEMT device 400 may include additional layers/structures/elements. For instance, the HEMT device 400 may include a buffer layer(s)/nucleation layer(s)/transition layer(s) between the substrate 404 and the channel layer 406. For example, an AIN buffer layer may be on the substrate 404 to provide an appropriate crystal structure transition between, for instance, a silicon carbide substrate 404 and the channel layer 406. The optional buffer/nucleation/transition layers may be deposited by MOCVD, MBE, and/or HYPE.

The HEMT device 400 may include one or more cap layers (not illustrated) on the barrier layer 408. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

According to examples of the present disclosure, the semiconductor structure 402 can include implanted regions 430.1 and 430.2 extending all the way through the barrier layer 408 and into the channel layer 406. The implanted regions 430.1 and 430.2 may include implanted dopants to provide for N-type doping of the semiconductor structure 402. In some embodiments, the implanted dopants may be silicon and/or germanium.

The implanted regions 430.1 and 430.2 may have a distribution of implanted dopants that extends to a depth from a surface (e.g., a top surface) of the semiconductor structure 402. The depth may be about 200 Angstroms or greater, such as about 250 Angstroms or greater, such as in a range of about 200 Angstroms to about 300 Angstroms. For instance, in some embodiments, the implanted regions 430.1 and 430.2 can extend to a depth of about 200 Angstroms to about 300 Angstroms beneath a surface of the Group III-nitride semiconductor structure. In particular, the implanted regions 430.1 and 430.2 can extend completely through the barrier layer 408 and into the channel layer 406.

The implanted regions 430.1 and 430.2 may have a peak dopant concentration. In some embodiments, a peak dopant concentration of the distribution of implanted dopants in the implanted regions 430.1 and 430.2 is in the channel layer 406. For instance, the implanted regions 430.1 and 430.2 may be doped such that the distribution of implanted dopants is greater at a portion of the implanted regions 430.1 and 430.2 at a depth as the channel layer 406 than at a portion of the implanted regions 430.1 and 430.2 at a depth in the barrier layer 408 (and/or another layer). In some examples, the distribution of implanted dopants may provide a substantially uniform concentration of implanted dopants throughout the implanted regions 430.1 and 430.2. In some embodiments, a peak dopant concentration of the distribution of implanted dopants can be about 1×10¹⁸ dopants/cm³.

Referring to FIG. 5, the HEMT device 400 may include a source contact 412 on the semiconductor structure 402 or otherwise contacting the semiconductor structure 402. More particularly, the HEMT device 400 may include a source contact 412 on the implanted region 430.1 or disposed at least partially within a recess in the implanted region 430.1.

The HEMT device 100 may include a drain contact 414 on the semiconductor structure 402 or otherwise contacting the semiconductor structure 402. More particularly, the HEMT device 400 may include a source contact 414 on the implanted region 430.2 or disposed at least partially within a recess in the implanted region 430.2. The source contact 412 and the drain contact 414 may be laterally spaced apart from each other.

In some embodiments, the source contact 412 and the drain contact 414 may include a metal that may form an ohmic contact to a Group III nitride-based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 412 may be an ohmic source contact 412. The drain contact 414 may be an ohmic drain contact 414. Thus, the source contact 412 and/or the drain contact 414 may include an ohmic contact portion in direct contact with the barrier layer 408.

As illustrated in FIG. 5, the source contact 412 and/or the drain contact 114 may include a plurality of layers to form an ohmic contact that may be provided as described, for example, in U.S. Pat. Nos. 8,563,372 and 9,214,352, the disclosures of which are incorporated by reference herein. In some examples, the source contact 412 may include a plurality of source contact layers, including a first source contact layer 412.1, a second source contact layer 412.2. and a third source contact layer 412.3. The first source contact layer 412.1 may be, for instance, titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. The second source contact layer 412.2 may include, for instance, alternating layers of, for instance, silicon and nickel (Ni) or other suitable metal (e.g., gold (Au), platinum (Pt), palladium (Pd)). The third source contact layer 412.3 may be for instance, a metal layer, such as gold (Au), platinum (Pt), palladium (Pd) or other suitable metal.

In some examples, the drain contact 414 may include a plurality of source contact layers, including a first source contact layer 414.1, a second source contact layer 414.2, and a third source contact layer 414.3. The first source contact layer 414.1 may be, for instance, titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. The second source contact layer 414.2 may include, for instance, alternating layers of, for instance, silicon and nickel (Ni) or other suitable metal (e.g., gold (Au), platinum (Pt), palladium (Pd)). The third source contact layer 414.3 may be for instance, a metal layer, such as gold (Au), platinum (Pt), palladium (Pd) or other suitable metal.

According to example aspects of the present disclosure, the ohmic contact(s) formed by the source contact 412 and/or the drain contact 414 can have a decreased contact resistance. For instance, example aspects of the present disclosure can provide for a decrease in contact resistance of the ohmic contact(s) compared to some existing semiconductor devices. For instance, in some embodiments, a contact resistance of the ohmic contact with the Group III-nitride semiconductor structure as described herein can be about 0.15 ohm-mm or less, such as about 0.10 ohm-mm or less, such as within a range of about 0.05 to about 0.15 ohm-mm.

The HEMT device 400 may include a gate contact 416 on the semiconductor structure 102 or otherwise contacting the semiconductor structure 402. The gate contact 416 may have a gate length. The gate length LG may be the length of the gate contact 416 along the portion of the gate contact 416 that is on the semiconductor structure 402 (e.g., the length of the lowermost portion of the gate contact 416 in contact with the semiconductor structure 402). In some embodiments, the gate length LG may be about 200 nm or less, such as about 100 nm or less, such as in a range of about 60 nm to about 100 nm, such as in a range of about 70 nm to about 90 nm.

The material of the gate contact 416 may be chosen based on the composition of the barrier layer 408, and may, in some embodiments, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN). In some embodiments, the gate contact 416 may be a T-shaped gate and/or a gamma gate, the formation of which is discussed by way of example in U.S. Pat. Nos. 8,049,252, 7,045,404, and 8,120,064, the disclosures of which are incorporated by reference herein.

The source contact 412 may be coupled to a reference signal such as, for example, a ground voltage or other reference signal at least partially through the implanted region 430.1. The coupling to the reference signal may be provided by a via 418 that extends from a lower surface of the substrate 104, through the substrate 404 and semiconductor structure 402 to the upper surface of the semiconductor structure 102 and/or to the implanted region 430.1. A back metal layer 420 may be on the lower surface the substrate 404 and on side walls of the via 418. Thus, the back metal layer 420, and a signal coupled thereto, may be electrically connected to the source contact 412.

In some embodiments, there is no source via 418, and the source contact 412 is formed on, in and/or through the semiconductor structure 402. Where there is no source via 418, the electrical connections to the source contact 412 may be made on the same side as the gate contact 416 and the drain contact 414. In some examples, the connections to the source contact 412, drain contact 414, and/or gate contact 416 may be made from the top and/or the bottom to provide for flip chip configuration of the HEMT device 400. In some examples, thermal paths may be provided from the top and/or bottom to provide flip chip configuration of the HEMT device 400.

The HEMT device 400 may include a dielectric structure 425 on the semiconductor structure 402. The dielectric structure 425 may include one or more dielectric layers, such as dielectric layer 426, dielectric layer 427, dielectric layer 428, and dielectric layer 429. Each of the dielectric layers 426, 427, 428, and 429 may be the same material and/or different materials. Each of the dielectric layers 426, 427, 428, and 429 may include materials to provide a thermal path for conduction of heat from the semiconductor structure 402. The dielectric structure 425 and/or each of the dielectric layers 426, 427, 428, and 429 may include SiO₂, Si, Ge, MgOx, MgNx, ZnO, SiNx, SiOx, alloys or layer sequences thereof, or epitaxial materials.

The dielectric structure 425 depicted in FIG. 5 has four dielectric layers 426, 427. 428, and 429 for purposes of illustration and discussion. Those of ordinary skill in the art, using the disclosures provided herein will understand that the HEMT device 400 may include more or fewer dielectric structures without deviating from the scope of the present disclosure.

A HEMT transistor cell may be formed by the active region between the source contact 112 and the drain contact 114 under the control of the gate contact 116 between the source contact 112 and the drain contact 114. FIG. 4 depicts a cross-sectional view of one unit or cell of an HEMT device 100 for purposes of illustration. The HEMT device unit or cell may be formed adjacent to additional HEMT device cells and may share, for instance, a source contact 112 with adjacent HEMT device cells.

The HEMT device 400 may include an isolation implant region 438. The isolation implant region 438 may provide isolation between adjacent HEMT device cells. The isolation implant region 438 may include implanted dopants (e.g., nitrogen) and may extend to a depth sufficient to provide electrical isolation between adjacent HEMT device cells.

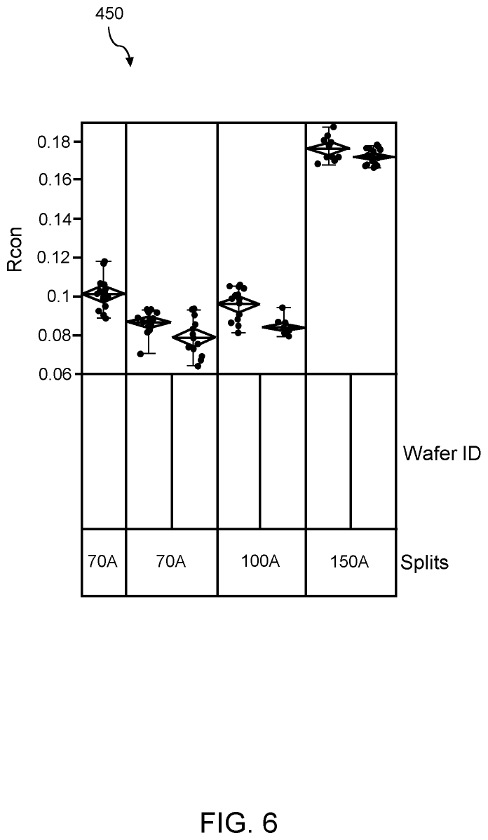

FIG. 6 depicts a plot 450 of contact resistance (e.g., measured using a transfer length method (TLM method)) for example semiconductor devices according to example embodiments of the present disclosure. FIG. 6 plots contact resistance Rcon on the vertical axis for semiconductor devices on seven different wafers (e.g., Wafers 1-7). Wafers 1-3 include semiconductor devices with thin barrier layers (e.g., about 70 A) and high aluminum mole fraction in the barrier layer (e.g., about 35%). Wafers 1-3 also include semiconductor devices with an ohmic contact in an implanted region in the semiconductor structure according to example aspects of the present disclosure. Wafers 4-5 include semiconductor devices with thin barrier layers (e.g., about 10 A) and high aluminum mole fraction in the barrier layer (e.g., about 35%). Wafers 4-5 also include semiconductor devices with an ohmic contact in an implanted region in the semiconductor structure according to example aspects of the present disclosure. Wafers 6-7 include semiconductor devices with barrier layers having a thickness of about 150 A and an aluminum concentration of about 25% (“POR devices”). As demonstrated, Wafers 1-5 demonstrate reduced contact resistance Rcon (e.g., less than 0.15 ohm-mm) relative to Wafers 6-7 with POR devices (e.g., greater than 0.15 ohm-mm).

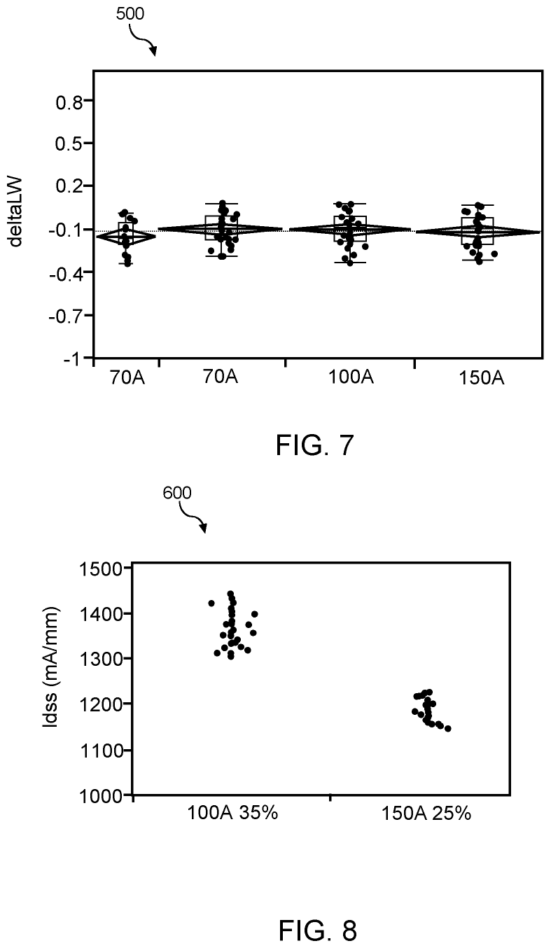

FIG. 7 depicts a plot 500 of deltaLW. Plot 500 indicates that measurement conditions for measuring contact resistance for semiconductors devices with thin barrier layers (e.g., about 70 A and about 100 A) and high aluminum mole fraction (e.g., about 35%) as well as for POR devices is about the same. More specifically, the deltaLW is a measurement of the as drawn photo mask to what is electrically measured based on the sheet resistance of the implant. Having a similar deltaLW across the different samples shows that the implant process was matched between the samples. This demonstrates the accuracy of Rcon reduction for devices with reduced barrier layer thickness and higher aluminum mole fraction concentration shown in FIG. 6.

FIG. 8 depicts a plot 600 of Idss for example semiconductor devices according to example aspects of the present disclosure. FIG. 8 plots Idss in mA/mm along the vertical axis. As shown due to the reduction in contact resistance RCon, the Idss for devices with thin barrier layers (e.g., about 100 A) and high aluminum mole fraction (e.g., about 35%) is higher relative to the Idss for POR devices.

FIG. 9 depicts a flow chart of an example method 700 according to example embodiments of the present disclosure. FIG. 9 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 702, the method 700 may include forming a Group III-nitride semiconductor structure on a substrate. For instance, the method 700 may include forming a Group III-nitride semiconductor structure 102 on a substrate 104, such as a silicon carbide substrate 104. The semiconductor structure 102 may be a multilayer structure and may include one or more of a barrier layer 108, a channel layer 106, and other layers. For instance, the Group III-nitride semiconductor structure can include a channel layer and a barrier layer on the channel layer. Details concerning these example layers are described above with reference to FIGS. 1-5. The Group III-nitride semiconductor structure may be formed, for instance, using metal-organic chemical vapor deposition (MOCVD), molecular beam epitaxy (MBE), or hydride vapor phase epitaxy (HVPE). The Group III-nitride semiconductor structure can be or can include part of a semiconductor device, such as a transistor (e.g., a HEMT).

At 704, the method 700 may include implanting dopants in the Group III-nitride semiconductor structure to form an implanted region (e.g., region 302) in the Group III-nitride semiconductor structure. The implanted region 302 can have a distribution of implanted dopants extending completely through the barrier layer 108 and into the channel layer 106. The implanted dopants may be, for example, silicon dopants, germanium dopants, and/or other suitable dopants.

For instance, in some embodiments, a mask is first formed on the semiconductor structure 102. The mask may include photoresist or any other suitable mask material, such as SiN and/or SiO₂. The mask may have a thickness selected to block implanted dopants during an implantation process. Next, windows can be opened in the mask to expose surface portions of the semiconductor structure 102. An implantation process is performed to implant dopants through the windows into the semiconductor structure 102 such that at least a portion of the implanted dopants are implanted through the semiconductor structure 102 and come to rest within the channel layer 106 and/or the barrier layer 108, forming the implanted region 302. The implanted dopants may form a distribution profile having a peak dopant concentration in a region, such as within the channel layer 106. The implanted region 302 may extend to a depth below the surface of the semiconductor structure 102. The depth may be 200 Angstroms or greater, such as 250 Angstroms or greater, such as in a range of 200 Angstroms to 300 Angstroms.

The implant conditions may be selected to provide implant region(s) 302 having a peak dopant concentration of 1×10¹⁸ ions/cm³ or greater. The implant conditions may also be selected to provide a distribution of implanted dopants having a substantially uniform concentration throughout the implanted region(s) 302. For instance, the implant process may include multiple implant steps to provide a relatively uniform profile of implanted dopants throughout the implanted region(s) 302. As such, the number of implant steps may depend on the thickness of the semiconductor structure 102 and the depth of the implanted region(s) 302. For example, the implant process may include a first implant step performed under a first set of implant conditions, and a subsequent implant step performed under a second set of implant conditions. However, more than two implant steps may be performed to provide the implanted region(s) 302.

In some embodiments, the dopant implantation process may be performed at room temperature. The implant energies and/or doses may be selected to provide an implant profile that achieves a desired sheet resistivity and/or permits fabrication of low resistivity ohmic contacts to the channel layer 106. For instance, the implanted dopants may include silicon and/or germanium dopants.

After formation of the implanted regions 302, the implanted dopants may be activated by an activation anneal. The mask may be removed prior to the implant activation anneal, for example, by way of a photoresist strip process and/or an etch process. However, the activation anneal may be performed with the mask in place.

The activation anneal may be performed in an inert atmosphere including, for example, N₂ and/or Ar. The activation anneal may be performed at a temperature sufficient to activate the implanted dopant ions but less than a temperature at which the semiconductor structure 102 deteriorates. In some embodiments, a protective layer (e.g., a SiN protective layer or other suitable protective layer) may be formed over the semiconductor structure. The protective layer may inhibit damage to the underlying semiconductor structure during high temperature process steps.

In some embodiments, the activation anneal may be performed at a temperature of about 1000° C. to about 1300° C., such as from about 1000° C. to about 1200° C. For instance, in some embodiments, implanting dopants can include annealing the dopants at an anneal temperature of about 1000° C. to about 1200°° C. The activation anneal may be performed in-situ and/or in a separate annealing chamber. The activation anneal may be performed for at least about 30 seconds or more, depending on the anneal temperature. For example, a rapid thermal anneal (RTA) at about 1300° C. may be performed for about 30 seconds, while a furnace anneal at about 1000° C. may be performed for about 30 minutes. The particular selection of activation times and temperatures may vary depending on the type of materials involved and the particular implant conditions employed. In particular embodiments, the anneal time may be in the range of about 30 seconds to about 30 minutes.

At 706, the method 700 may include forming a recess in the implanted region. The recess can extend through the barrier layer into the channel layer. For instance, in some embodiments, the recess can extend a depth that is less than a depth of the implanted region 302 but greater than a thickness of the barrier layer 108. As one example, in some embodiments, the recess can extend a depth in a range from about 200 Angstroms to about 300 Angstroms.

For instance, in some embodiments, the implanted region 302 can be etched to form the recess. For instance, an etch process may be performed to remove exposed portions of the semiconductor structure 102 to form the recess. The etch process may etch the semiconductor structure to an etch depth. The etch depth may be in a range of about 200 Angstroms or more, such as about 250 Angstroms or more, such as in a range of about 200 Angstroms to about 300Angstroms. In some examples, the etch process may be an ALE process. In some examples, the etch process may be a plasma-based dry etch process. The plasma-based dry etch process may use a pulsed plasma or provide continuous exposure to plasma.

At 708, the method 700 may include forming an ohmic contact in the recess. The ohmic contact can be formed by any suitable process. In some embodiments, metal may be deposited on the exposed implanted region(s) 302 of the semiconductor structure 102, for example by evaporation, to provide the ohmic contact 304. Suitable contact metals may include, for instance, titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSix, titanium silicide (TiSi), titanium nitride (TiN), tungsten silicon nitride (WSiN), platinum (Pt) and the like. The ohmic contact 304 can be a source contact (e.g., an ohmic source contact) and/or a drain contact (e.g., an ohmic drain contact) and/or other suitable contact.

In some embodiments, the deposited metal may be annealed at a relatively high temperature to provide the ohmic contact 304. For example, the anneal may be an anneal at a temperature of greater than about 900° C. in an atmosphere of an inert gas such as N₂ or Ar. Through the use of an ohmic contact anneal, the resistance of the ohmic contact 304 may be reduced. As with the implant activation anneal, a protective layer may be used during the high temperature process steps to inhibit damage to the semiconductor structure 102. It will be appreciated, however, that due to the presence of the implanted regions 302 in the semiconductor structure 102, it may not be necessary to anneal the deposited metal in order to form an ohmic contact 304. That is, the metal may be ohmic as deposited.

In addition, since the ohmic contact 304 is formed on the implanted region 302, the ohmic contact 304 may have a lower resistivity than ohmic contacts formed on non-implanted regions. Thus, the on-resistance of devices formed according to some embodiments of the present disclosure may be reduced. For instance, in some embodiments, a contact resistance of the ohmic contact with the Group III-nitride semiconductor structure may be about 0.15 ohm-mm or less. For instance, in some embodiments, a contact resistance of the ohmic contact with the Group III-nitride semiconductor structure may be about 0.10 ohm-mm or less. For instance, in some embodiments, a contact resistance of the ohmic contact with the Group III-nitride semiconductor structure may be in a range of about 0.05 to about 0.15 ohm-mm or less.

At 710, the method 700 may include forming a gate contact on the semiconductor structure. For instance, the method 700 may include forming a gate contact 116 on a semiconductor structure 102 as shown in FIG. 1. The material of the gate contact 116 may be chosen based on the composition of the barrier layer 108, and may, in some embodiments, be a Schottky contact. Materials capable of making a Schottky contact to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN). The gate contact may be formed using a suitable metal deposition process, such as a chemical vapor deposition (CVD) process, a physical vapor deposition (PVD) process, a sputtering process, an atomic layer deposition (ALD) process, or other suitable deposition process. The gate contact can have a gate length. The gate length can be less than about 100 nm, such as in a range of about 60 nm to about 100 nm, such as in a range of about 80 nm to about 100 nm.

Example embodiments of the present disclosure are set forth below. Any of the below features or examples may be used in combination with any of the embodiments or features provided in the present disclosure.

One example embodiment of the present disclosure is directed to a semiconductor device. The semiconductor device includes a Group III-nitride semiconductor structure. The Group III-nitride semiconductor structure includes a channel layer and a barrier layer on the channel layer. The semiconductor device includes an implanted region extending into the channel layer. The implanted region includes a distribution of implanted dopants. The semiconductor device includes a recess in the implanted region. The recess extends through the barrier layer into the channel layer. The semiconductor device includes an ohmic contact within the recess.

In some embodiments, a contact resistance of the ohmic contact with the Group III-nitride semiconductor structure is about 0.15 ohm-mm or less. In some embodiments, a contact resistance of the ohmic contact with the Group III-nitride semiconductor structure is about 0.10 ohm-mm or less. In some embodiments, a contact resistance of the ohmic contact with the Group III-nitride semiconductor structure is in a range of about 0.05 to about 0.15 ohm-mm.

In some embodiments, the barrier layer comprises Al_{y}Ga_{1-y}N, wherein y is in a range of about 0.25 to about 0.4, wherein the barrier layer has a thickness of less than about 130 Angstroms. In some embodiments, y is in a range of 0.35 to about 0.4. In some embodiments, the barrier layer has a thickness in a range of about 70 Angstroms to about 100 Angstroms.

In some embodiments, the semiconductor device comprises a gate contact. The gate contact has a gate length of about 100 nm or less. In some embodiments, the gate contact has a gate length in a range of about 60 nm to about 100 nm.

In some embodiments, the implanted dopants comprise silicon. In some embodiments, the implanted dopants comprise germanium. In some embodiments, the implanted region extends to a depth of about 200 Angstroms to about 300 Angstroms beneath a surface of the Group III-nitride semiconductor structure. In some embodiments, a peak dopant concentration of the distribution of implanted dopants in the implanted region is in the channel layer. In some embodiments, a peak dopant concentration of the distribution of implanted dopants comprises about 1×10¹⁸ dopants/cm³.

In some embodiments, the ohmic contact is a source contact or a drain contact. In some embodiments, the channel layer comprises AlₓGa₁₋ₓN, wherein x is about 0.1 or less. In some embodiments, the Group III-nitride semiconductor structure is on a silicon carbide substrate. In some embodiments, the semiconductor device comprises a high electron mobility transistor. In some embodiments, the semiconductor device is associated with an operating frequency of greater than about 8 GHz.

Another example embodiment of the present disclosure is directed to a transistor device. The transistor device includes a Group III-nitride semiconductor structure. The Group III-nitride semiconductor structure includes a channel layer and a barrier layer on the channel layer. The transistor device includes a gate contact on the barrier layer. The gate contact has a gate length of less than about 100 nm. The transistor device includes an implanted region in the Group III-nitride semiconductor structure. The implanted region has a distribution of implanted dopants. The transistor device has an ohmic contact on the implanted region. A contact resistance of the ohmic contact with the Group III-nitride semiconductor structure is about 0.15 ohm-mm or less.

In some embodiments, a contact resistance of the ohmic contact with the Group III-nitride semiconductor structure is about 0.10 ohm-mm or less. In some embodiments, the barrier layer comprises Al_{y}Ga_{1-y}N, wherein y is in a range of about 0.25 to about 0.4, wherein the barrier layer has a thickness of less than about 130 Angstroms.

In some embodiments, the ohmic contact is in a recess in the implanted region of the Group III-nitride semiconductor structure, the recess extending through the barrier layer. In some embodiments, the ohmic contact is a source contact or a drain contact of the transistor device. In some embodiments, the gate contact has a gate length in a range of about 60 nm to about 100 nm.

In some embodiments, the implanted dopants comprise silicon. In some embodiments, the implanted dopants comprise germanium. In some embodiments, the implanted region extends to a depth of about 200 Angstroms to about 300 Angstroms beneath a surface of the Group III-nitride semiconductor structure. In some embodiments, a peak dopant concentration of the distribution of implanted dopants in the implanted region is in the channel layer. In some embodiments, a peak dopant concentration of the distribution of implanted dopants comprises about 1×10¹⁸ dopants/cm³.

In some embodiments, the ohmic contact is a source contact or a drain contact. In some embodiments, the channel layer comprises AlₓGa₁₋ₓN, wherein x is about 0.1 or less. In some embodiments, the Group III-nitride semiconductor structure is on a silicon carbide substrate. In some embodiments, the semiconductor device comprises a high electron mobility transistor. In some embodiments, the semiconductor device is associated with an operating frequency of greater than about 8 GHz.

Another example embodiment of the present disclosure is directed to a method of forming a semiconductor device. The method includes forming a Group III-nitride semiconductor structure on a substrate, the Group III-nitride semiconductor structure having a channel layer and a barrier layer on the channel layer. The method includes implanting dopants in the Group III-nitride semiconductor structure to form an implanted region in the Group III-nitride semiconductor structure, the implanted region having a distribution of implanted dopants extending into the channel layer. The method includes forming a recess in the implanted region, the recess extending through the barrier layer into the channel layer. The method includes forming an ohmic contact in the recess.

In some embodiments, implanting dopants comprises annealing the dopants at an anneal temperature of about 1000° C. to about 1200° C. In some embodiments, implanting dopants comprises implanting silicon dopants. In some embodiments, implanting dopants comprises implanting germanium dopants. In some embodiments, implanting dopants comprises implanting dopants such that a peak dopant concentration is in the channel layer. In some embodiments, implanting dopants comprises implanting dopants such that a peak dopant concentration of the distribution of implanted dopants comprises about 1×10¹⁸ dopants/cm³.

In some embodiments, the barrier layer comprises Al_{y}Ga_{1-y}N, wherein y is in a range of about 0.25 to about 0.4. The barrier layer has a thickness of less than about 130 Angstroms.

In some embodiments, the method includes forming a gate contact on the Group III-nitride semiconductor structure. The gate contact has a gate length of less than about 100 nm.

In some embodiments, the ohmic contact is a source contact or a drain contact. In some embodiments, the channel layer comprises AlₓGa₁₋ₓN, wherein x is about 0.1 or less.

In some embodiments, a contact resistance of the ohmic contact with the Group III-nitride semiconductor structure is about 0.15 ohm-mm or less. In some embodiments, a contact resistance of the ohmic contact with the Group III-nitride semiconductor structure is about 0.10ohm-mm or less. In some embodiments, a contact resistance of the ohmic contact with the Group III-nitride semiconductor structure is in a range of about 0.05 to about 0.15 ohm-mm or less.

In some embodiments, the substrate comprises a silicon carbide substrate. In some embodiments, the semiconductor device comprises a high electron mobility transistor.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a Group III-nitride semiconductor structure, the Group III-nitride semiconductor structure comprising a channel layer and a barrier layer on the channel layer;
an implanted region extending into the channel layer, the implanted region comprising a distribution of implanted dopants; and
a recess in the implanted region, the recess extending through the barrier layer into the channel layer; and
an ohmic contact within the recess.

2. The semiconductor device of claim 1, wherein a contact resistance of the ohmic contact with the Group III-nitride semiconductor structure is about 0.15 ohm-mm or less.

3. The semiconductor device of claim 1, wherein a contact resistance of the ohmic contact with the Group III-nitride semiconductor structure is about 0.10 ohm-mm or less.

4. The semiconductor device of claim 1, wherein a contact resistance of the ohmic contact with the Group III-nitride semiconductor structure is in a range of about 0.05 to about 0.15 ohm-mm.

5. The semiconductor device of claim 1, wherein the barrier layer comprises Al_{y}Ga_{1-y}N, wherein y is in a range of about 0.25 to about 0.4, wherein the barrier layer has a thickness of less than about 130 Angstroms.

6. The semiconductor device of claim 5, wherein y is in a range of 0.35 to about 0.4.

7. The semiconductor device of claim 5, wherein the barrier layer has a thickness in a range of about 70 Angstroms to about 100 Angstroms.

8. (canceled)

9. The semiconductor device of claim 8, wherein the gate contact has a gate length in a range of about 60 nm to about 100 nm.

10. The semiconductor device of claim 1, wherein the implanted dopants comprise silicon.

11. The semiconductor device of claim 1, wherein the implanted dopants comprise germanium.

12. The semiconductor device of claim 1, wherein the implanted region extends to a depth of about 200 Angstroms to about 300 Angstroms beneath a surface of the Group III-nitride semiconductor structure.

13. The semiconductor device of claim 1, wherein a peak dopant concentration of the distribution of implanted dopants in the implanted region is in the channel layer.

14. The semiconductor device of claim 1, wherein a peak dopant concentration of the distribution of implanted dopants comprises about 1×10¹⁸ dopants/cm³.

15. The semiconductor device of claim 1, wherein the ohmic contact is a source contact or a drain contact.

16. The semiconductor device of claim 1, wherein the channel layer comprises AlₓGa₁₋ₓN, wherein x is about 0.1 or less.

17. The semiconductor device of claim 1, wherein the Group III-nitride semiconductor structure is on a silicon carbide substrate.

18. The semiconductor device of claim 1, wherein the semiconductor device comprises a high electron mobility transistor.

19. The semiconductor device of claim 1, wherein the semiconductor device is associated with an operating frequency of greater than about 8 GHz.

20. A transistor device, comprising:
a Group III-nitride semiconductor structure, the Group III-nitride semiconductor structure comprising a channel layer and a barrier layer on the channel layer;
a gate contact on the barrier layer, the gate contact having a gate length of less than about 100 nm;
an implanted region in the Group III-nitride semiconductor structure, the implanted region comprising a distribution of implanted dopants;
an ohmic contact on the implanted region; and
wherein a contact resistance of the ohmic contact with the Group III-nitride semiconductor structure is about 0.15 ohm-mm or less.

21-34. (canceled)

35. A method of forming a semiconductor device, comprising:
forming a Group III-nitride semiconductor structure on a substrate, the Group III-nitride semiconductor structure comprising a channel layer and a barrier layer on the channel layer;
implanting dopants in the Group III-nitride semiconductor structure to form an implanted region in the Group III-nitride semiconductor structure, the implanted region having a distribution of implanted dopants extending into the channel layer;
forming a recess in the implanted region, the recess extending through the barrier layer into the channel layer; and
forming an ohmic contact in the recess.

36-49. (canceled)
